(19) United States
(12) Patent Application Publication
(10) Pub. No.: US 2012/0151296 A1
(43) Pub. Date: Jun. 14, 2012

(54) DATA PROCESSING DEVICE AND DATA PROCESSING METHOD

(75) Inventor: Tomoki NISHIKAWA, Wakayama (JP)

(73) Assignee: Panasonic Corporation, Osaka (JP)

(21) Appl. No.: 13/401,073

(22) Filed: Feb. 21, 2012

Related U.S. Application Data
(63) Continuation of application No. PCT/JP2010/005083, filed on Aug. 17, 2010.

(30) Foreign Application Priority Data
Aug. 25, 2009 (JP) 2009-194478

(51) Int. Cl. H03M 13/29; G06F 11/10

(52) U.S. Cl. 714/755; 714/776; 714/E11.032

(57) ABSTRACT

A data processing device includes: an error corrector configured to perform demodulation and error correction on a received signal to output error-corrected data, the received signal transmitting packets which include packet identifiers and are encrypted by broadcast encryption; and a transport stream generator configured to generate a transport stream based on the error-corrected data. The error corrector selects the packets including a set packet identifier, and outputs the selected packets as the error-corrected data.

### CROSS-REFERENCE TO RELATED APPLICATIONS

This is a continuation of PCT International Application PCT/JP2010/005083 filed on Aug. 17, 2010, which claims priority to Japanese Patent Application No. 2009-194478 filed on Aug. 25, 2009. The disclosures of these applications including the specifications, the drawings, and the claims are hereby incorporated by reference in their entirety.

### BACKGROUND

The present disclosure relates to data processing devices and methods for processing digital television broadcast signals, and the like.

In processing digital television broadcast signals, processes are basically performed according to the following flow. That is, from signals received by an antenna, a necessary signal is selected by a tuner, and a transport stream (TS) is generated. Then, filtering the TS based on IDs of packets, decrypting (descrambling) the TS with respect to broadcast encryption, section filtering, storing, and an AV process are performed (see, for example, Japanese Patent Publication No. H07-327051, Japanese Patent Publication No. H07-297855, and Japanese Patent Publication No. H09-275381).

### SUMMARY

However, in the descrambling process of decrypting the TS with respect to the broadcast encryption, a large number of operations has to be performed, and thus a circuit for performing the descrambling process has to be operated at a high speed, which increases power consumption of the circuit. Moreover, when data before the descrambling is temporarily stored in a shared memory, a large portion of the transmission bandwidth of the shared memory is occupied for the descrambling process, which reduces the speed of other processes using the shared memory.

It is an objective of the present disclosure to reduce power consumption of a data processing device.

An example data processing device of the present disclosure includes: an error corrector configured to perform demodulation and error correction on a received signal to output error-corrected data, the received signal transmitting packets which include packet identifiers and are encrypted by broadcast encryption; and a transport stream generator configured to generate a transport stream based on the error-corrected data. The error corrector selects the packets including a set packet identifier, and outputs the selected packets as the error-corrected data.

With this configuration, a packet including a set packet identifier is selected, so that it is possible to reduce the number of packets on which processes are performed. Thus, power consumption of the data processing device can be reduced.

An example data processing method of the present disclosure includes: performing demodulation and error correction on a received signal to output error-corrected data, the received signal transmitting packets which include packet identifiers and are encrypted by broadcast encryption; and generating a transport stream based on the error-corrected data. In the performing, the packets including a set packet identifier are selected, and the selected packets are output as the error-corrected data.

According to the disclosure, power consumption of the data processing device can be reduced. Moreover, it is possible to reduce the number of packets on which processes are performed, so that the speed of processes other than processes performed by the data processing device can be improved when a shared memory is used.

### BRIEF DESCRIPTION OF THE DRAWINGS

FIG. 1 is a block diagram illustrating an example configuration of a receiver including a data processing device according to an embodiment of the present invention.

FIG. 2A is a view illustrating an example configuration of a TS packet (section format). FIG. 2B is a view illustrating an example configuration of a TS packet (PES format).

FIG. 3 is a view illustrating an example format of a TS packet in detail.

FIG. 4 is a flow chart illustrating a process flow in the data processing device in FIG. 1.

FIG. 5 is a block diagram illustrating an example configuration of the error corrector of FIG. 1.

FIG. 6 is a block diagram illustrating a first variation of the error corrector of FIG. 5.

FIG. 7 is a block diagram illustrating a second variation of the error corrector of FIG. 5.

FIG. 8 is a block diagram illustrating a third variation of the error corrector of FIG. 5.

FIG. 9 is a block diagram illustrating a fourth variation of the error corrector of FIG. 5.

FIG. 10 is a view illustrating an example format of the adaptation field of FIG. 3.

FIG. 11 is a flow chart illustrating a process flow in a variation of the data processing device of FIG. 1.

FIG. 12 is a block diagram illustrating a variation of part of the data processing device of FIG. 1.

### DETAILED DESCRIPTION

Embodiments of the present invention will be described in detail below with reference to the drawings. In the drawings, components indicated by reference numbers having the same last two digits correspond to each other, and are identical or equivalent components.

Functional blocks to be described herein can be typically implemented by hardware. For example, the functional blocks can be formed on a semiconductor substrate as part of an integrated circuit (IC). The IC as used herein includes a large-scale integrated circuit (LSI), an application-specific integrated circuit (ASIC), a gate array, a field programmable gate array (FPGA), and the like. Alternatively, some or all of the functional blocks may be implemented by software. For example, such a functional block can be implemented by a program executable on a processor. In other words, the functional blocks to be described herein may be implemented by hardware, by software, or by any combination of hardware and software.

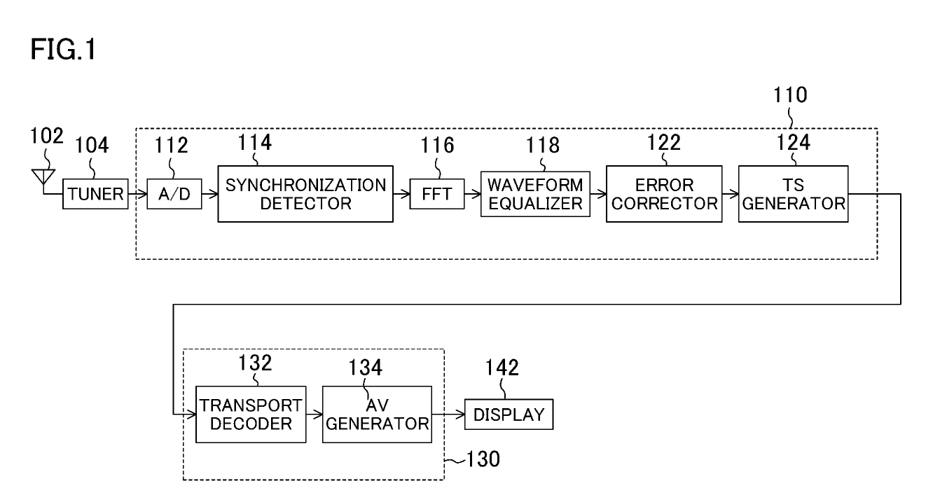

FIG. 1 is a block diagram illustrating an example configuration of a receiver including a data processing device according to an embodiment of the present invention. The receiver of FIG. 1 includes a tuner 104, a front end section 110, a back end section 130, and a display 142. The front end section 110 and the back end section 130 are included in the data processing device.

The front end section 110 includes an A/D converter 112, a synchronization detector 114, a fast Fourier transformer 116, a waveform equalizer 118, an error corrector 122, and a transport stream (TS) generator 124. The back end section 130 includes a transport decoder 132, and an audiovisual (AV) generator 134 serving as a video generator. The front end section 110 may be formed on a single semiconductor substrate, and the back end section 130 may be formed on another single semiconductor substrate.

As an example, reception of a signal of an orthogonal frequency division multiplexing (OFDM) scheme by the receiver of FIG. 1 will be described, where the OFDM scheme is used in the digital terrestrial television broadcasting in Japan, Europe, and other areas. The receiver of FIG. 1 may receive only one segment, for example, of a plurality of segments included in an OFDM signal, or may receive more of the segments. A signal received by the receiver of FIG. 1 transmits a plurality of TS packets (hereinafter also simply referred to as packets) each including a packet identifier.

An antenna 102 receives signals transmitted from broadcast stations, or the like, and feeds the received signals to the tuner 104. The tuner 104 selects a signal having a desired frequency among the fed received signals, and outputs the selected signal to the A/D converter 112. The A/D converter 112 performs A/D conversion on the input signal, and outputs the converted signal to the synchronization detector 114.

The synchronization detector 114 detects establishment of synchronization and the synchronization state of the received signal. For example, when a pilot signal, which is a known signal, is received at predetermined timing, this indicates that establishment of synchronization has been detected. The synchronization detector 114 outputs the synchronized signal to the fast Fourier transformer 116. The fast Fourier transformer 116 performs fast Fourier transform on the input signal, and outputs the transformed signal to the waveform equalizer 118.

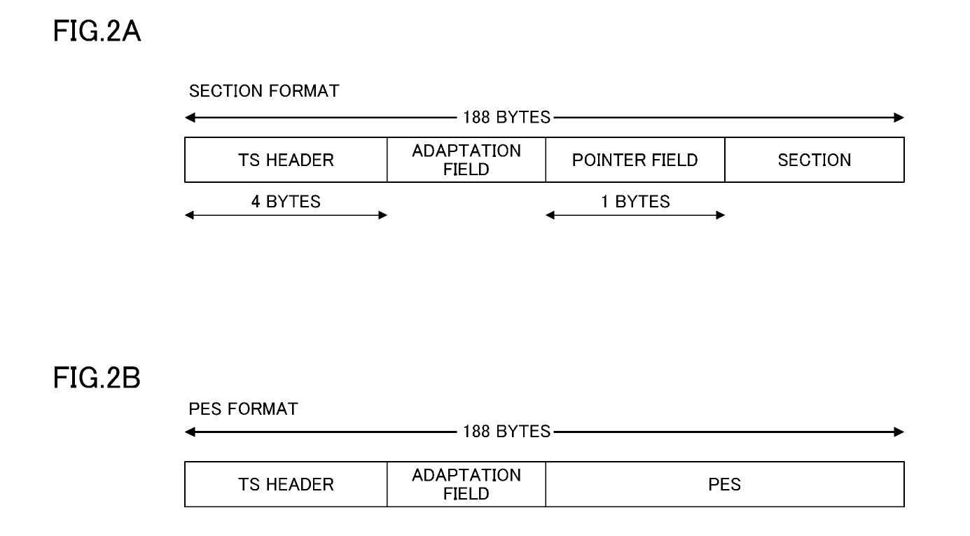

FIG. 2A is a view illustrating an example configuration of a TS packet (section format). FIG. 2B is a view illustrating an example configuration of a TS packet (packetized elementary stream (PES) format). TS packets of the section format and the PES format each include a header and an adaptation field, and have a packet size of 188 bytes. The TS packet includes a section field or a PES field following the adaptation field. Section data (e.g., PID) is stored in the section field, where the section data represents, for example, the relationship between a program included in a TS and program components included in the program of the stream. The information is called program specific information (PSI). A payload of the TS packet, that is, data of the section field, the PES field, and the like is encrypted by broadcast encryption, and the entirety of the TS packet is Reed-Solomon encoded.

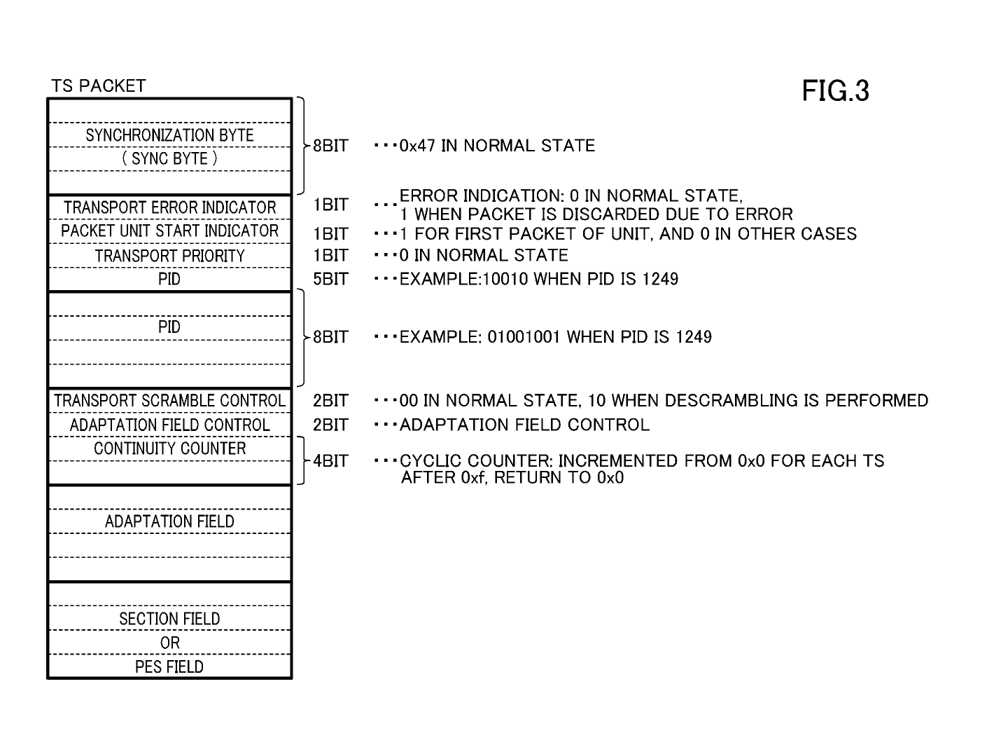

FIG. 3 is a view illustrating an example format of the TS packet in detail. The TS packet is specified in, for example, moving picture experts group-2 (MPEG-2) standard. The header of the TS packet includes an 8-bit synchronization byte and a 13-bit packet identifier (PID).

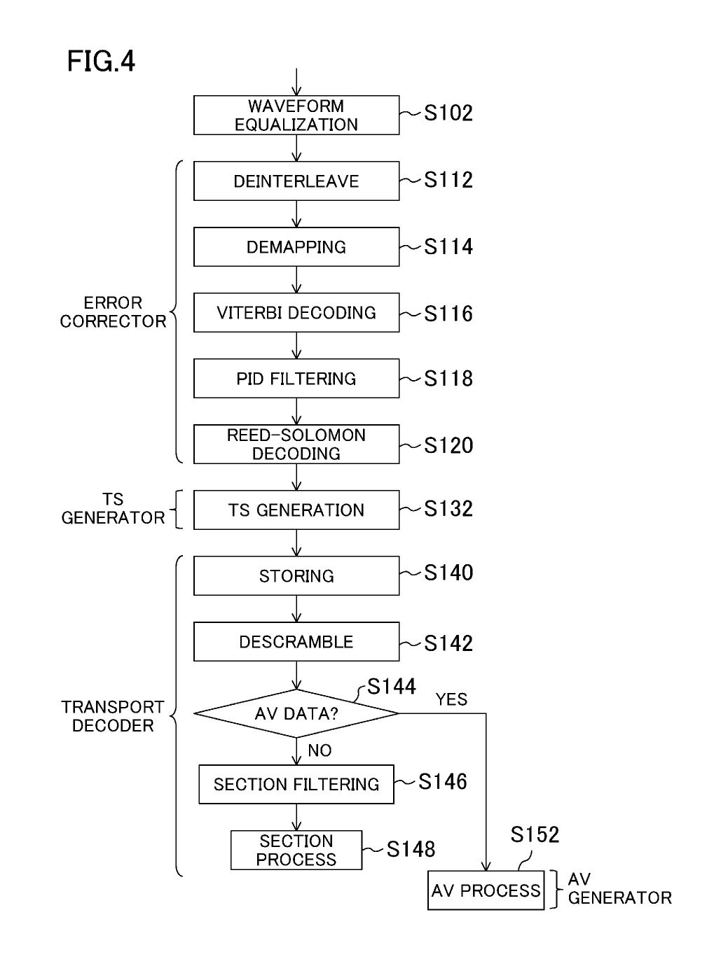

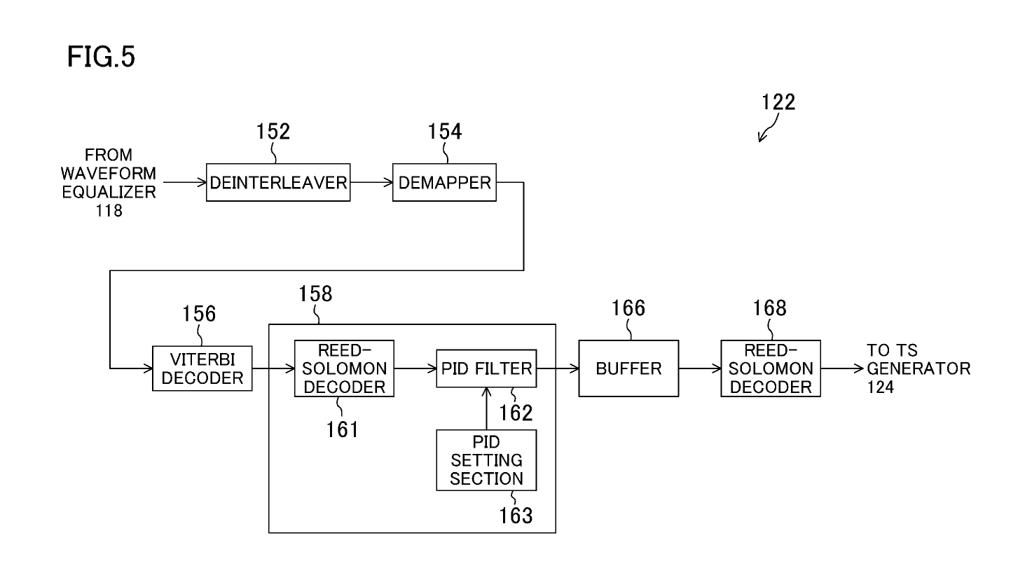

FIG. 4 is a flow chart illustrating a process flow in the data processing device of FIG. 1. FIG. 5 is a block diagram illustrating an example configuration of the error corrector 122 of FIG. 1. The error corrector 122 includes a deinterleaver 152, a demapper 154, a Viterbi decoder 156, a filter section 158, a buffer 166, and a Reed-Solomon decoder 168. The filter section 158 includes a Reed-Solomon decoder 161, a PID filter 162, and a PID setting section 163. With reference to FIGS. 1-5, operation of the data processing device of FIG. 1 will be described.

In S102 of FIG. 4, the waveform equalizer 118 equalizes the waveform of a signal input from the fast Fourier transformer 116, and outputs the equalized signal to the deinterleaver 152 of the error corrector 122. In S112, the deinterleaver 152 performs a deinterleaving process on the equalized signal, and outputs the obtained result to the demapper 154. In S114, the demapper 154 performs a demapping process (demodulation process) to convert the result of the deinterleaving process into corresponding data, and outputs the obtained result to the Viterbi decoder 156. In S116, the Viterbi decoder 156 performs Viterbi decoding on the result of the demapping process, and outputs the obtained result to the Reed-Solomon decoder 161.

In S118, the filter section 158 performs a PID filtering process on the result of the Viterbi decoding. More specifically, the following process is performed. PIDs of packets which should be passed through the filter section 158 are set in the PID setting section 163. The PID setting section 163 outputs the set PIDs to the PID filter 162. The Reed-Solomon decoder 161 performs a Reed-Solomon decoding process on part of the result of the Viterbi decoding, the part including PIDs. The Reed-Solomon decoder 161 outputs the result of the Reed-Solomon decoding process to the PID filter 162. As illustrated in FIG. 3, it is known that two bytes following a synchronization byte include a PID. Thus, here, the Reed-Solomon decoder 161 first performs the Reed-Solomon decoding process on the result of the Viterbi decoding to search synchronization bytes, and performs the Reed-Solomon decoding process on two bytes following each synchronization byte. The PID filter 162 selects packets including the PIDs set to the PID setting section 163 from the result of the Reed-Solomon decoding process, and outputs the selected packets to the buffer 166.

The buffer 166 stores the packets output from the PID filter 162, and outputs the stored packets to the Reed-Solomon decoder 168. In S120, the Reed-Solomon decoder 168 performs a Reed-Solomon decoding process also on parts of the packets output from the buffer 166, the parts having not been processed in the Reed-Solomon decoder 161. The Reed-Solomon decoder 168 outputs the process result to the TS generator 124.

As described above, the error corrector 122 performs demodulation and error correction on the received signal, and outputs the error-corrected data to the TS generator 124. Here, the error corrector 122 selects the packets including the set packet identifiers, and outputs the selected packets as the error-corrected data.

In S132, the TS generator 124 generates a TS from the process result of the Reed-Solomon decoder 168. That is, the TS generator 124 outputs the packets processed in the Reed-Solomon decoder 168 to the transport decoder 132 at regular intervals at a predetermined rate.

In S140, the transport decoder 132 selects packets from the generated TS, and outputs the selected packets to a memory, in which the packets are stored. Then, in S142, the transport decoder 132 reads the packets from the memory, and decrypts with respect to the broadcast encryption, that is, descrambles the read packets.

In S144, the transport decoder 132 determines whether or not the descrambled packets include AV data. When the descrambled packets include AV data, the process proceeds to S152, whereas when the descrambled packets do not include AV data, the process proceeds to S146. In S146, the transport decoder 132 performs section filtering on the packets which do not include AV data, that is, selects packets required to playback a program. In S148, the transport decoder 132 performs a section process on the packets selected in S146 to utilize section data included in the packets.

In S152, the transport decoder 132 selects the packets including AV data, and outputs the selected packets to the AV generator 134. The AV generator 134 decodes video and audio from the packets which are selected by the transport decoder 132, and which include AV data, and outputs the obtained video and audio signals to the display 142. The display 142 displays video images and outputs audio based on the video signal and the audio signal obtained in S152.

In the descrambling process of decrypting the packets with respect to broadcast encryption, a large number of operations has to be performed. Thus, the transport decoder 132 which performs descrambling has to be operated at a high speed. For this reason, the back end section 130 including the transport decoder 132 is operated, for example, at a clock frequency more than ten times as high as the clock frequency of the front end section 110.

In the data processing device of FIG. 1, the filter section 158 passes only necessary packets according to PIDs, and thus, it is not necessary for the TS generator 124 to output unnecessary packets, and it is not necessary for the transport decoder 132 to perform the descrambling process on the unnecessary packets. Thus, it is possible to reduce power consumption of the TS generator 124 and the transport decoder 132. Alternatively, data before being descrambled may be temporarily stored in a shared memory. In this case, according to the data processing device of FIG. 1, the transmission bandwidth of the shared memory occupied for the descrambling process decreases. Thus, a transmission bandwidth assigned to other processes using the shared memory can be increased, which improves the speed of the other processes using the shared memory.

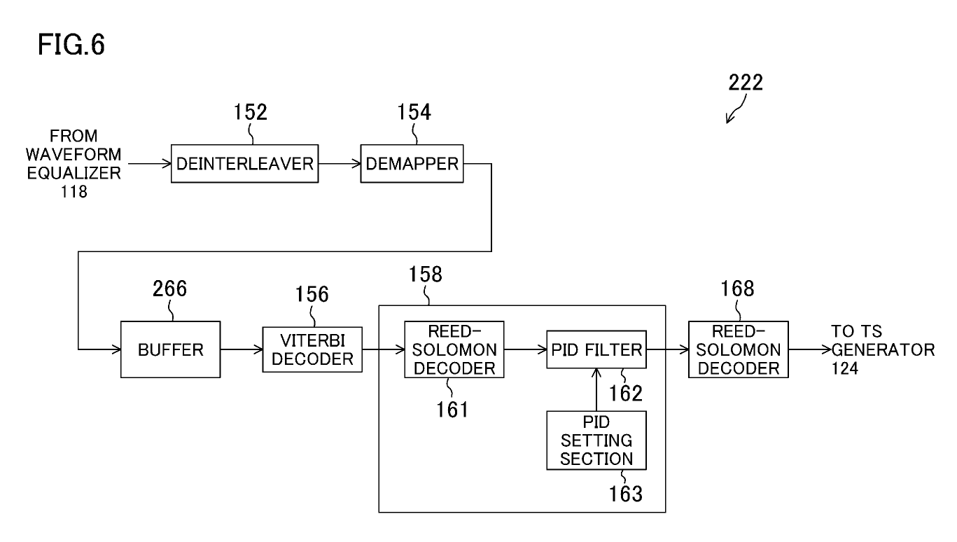

A variation of the error corrector 122 of FIG. 5 will be described below. FIG. 6 is a block diagram illustrating a first variation of the error corrector of FIG. 5. An error corrector 222 of FIG. 6 is different from the error corrector 122 of FIG. 5 in that a buffer 266 instead of the buffer 166 is provided upstream of the Viterbi decoder 156. The buffer 266 stores the result of the demapping process by the demapper 154, and then outputs the stored result to the Viterbi decoder 156. Other configurations are similar to those of the error corrector 122 of FIG. 5.

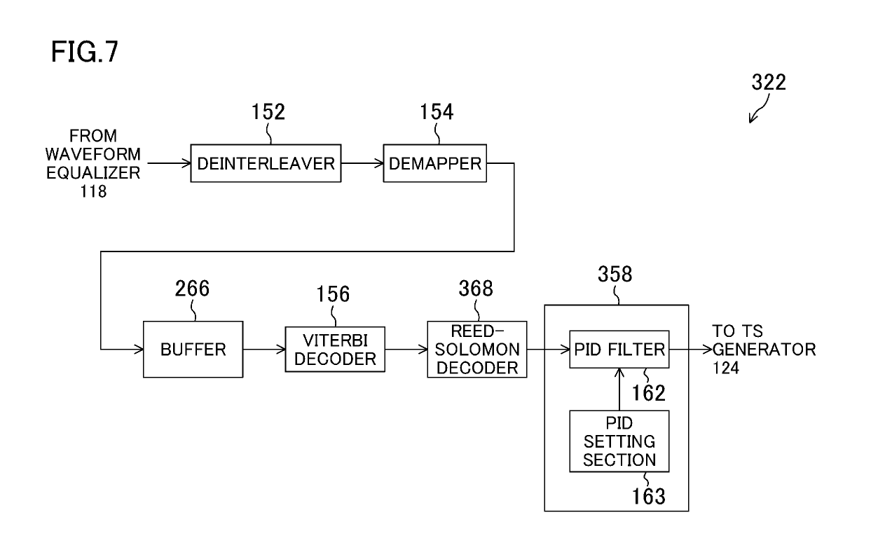

FIG. 7 is a block diagram illustrating a second variation of the error corrector of

FIG. 5. An error corrector 322 of FIG. 7 is different from the error corrector 222 of FIG. 6 in that a filter section 358 and a Reed-Solomon decoder 368 are provided instead of the filter section 158 and the Reed-Solomon decoder 168. The filter section 358 is different from the filter section 158 in that the Reed-Solomon decoder 161 is not provided.

The Reed-Solomon decoder 368 performs a Reed-Solomon decoding process on a result of Viterbi decoding, and outputs the result to the PID filter 162. Here, the Reed-Solomon decoder 368 performs the Reed-Solomon decoding process on the entirety of packets. The PID filter 162 selects only packets including PIDs output from the PID setting section 163 from the result of the Reed-Solomon decoding process, and outputs the selected packets to the TS generator 124. With the error corrector 322 of FIG. 7, the number of Reed-Solomon decoders can be reduced.

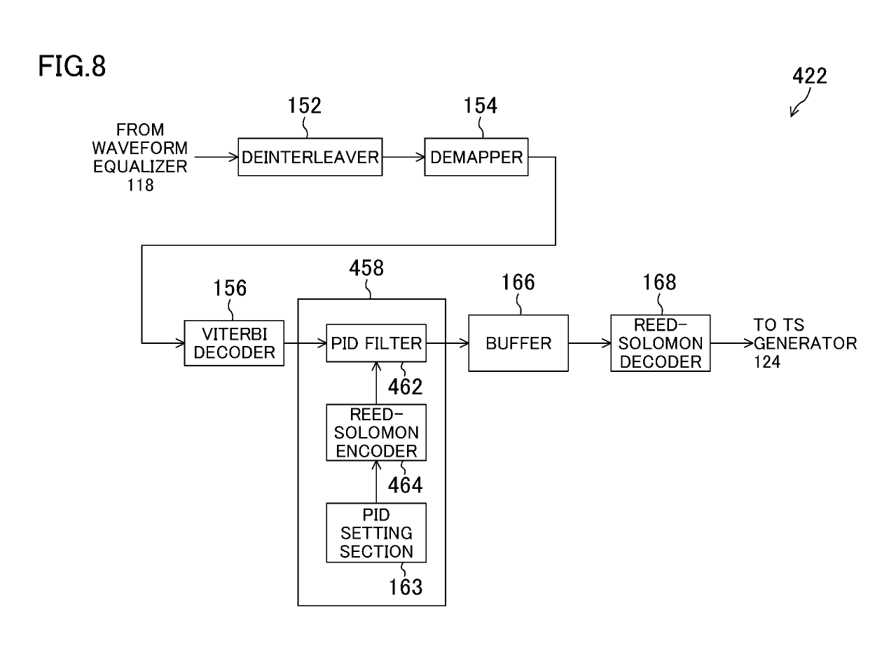

FIG. 8 is a block diagram illustrating a third variation of the error corrector of FIG. 5. An error corrector 422 of FIG. 8 is different from the error corrector 122 of FIG. 5 in that a filter section 458 is provided instead of the filter section 158. The filter section 458 includes a PID filter 462, a Reed-Solomon encoder 464, and a PID setting section 163.

The filter section 458 performs the following PID filtering process on a result of Viterbi decoding. In the PID setting section 163, PIDs of packets which should be passed through the filter section 458 are set. The PID setting section 163 outputs the set PIDs to the Reed-Solomon encoder 464.

The Reed-Solomon encoder 464 performs a Reed-Solomon encoding process on leading three bytes of FIG. 3 (that is, from the synchronization byte through the PID), and outputs the encoded result to the PID filter 462. The encoded PIDs here are the PIDs output from the PID setting section 163. Moreover, for each PID, the encoding process is performed on the leading three bytes of FIG. 3 in terms of all combinations of values of a transport error indicator and values of a packet unit start indicator. From the result of the Viterbi decoding, the PID filter 462 selects packets including the encoded result output from the Reed-Solomon encoder 464, and outputs the selected packets to the buffer 166.

With the error corrector 422 of FIG. 8, it is not necessary to perform the Reed-Solomon decoding process on synchronization bytes and PIDs of all packets, so that the number of operations for the PID filtering process can be reduced.

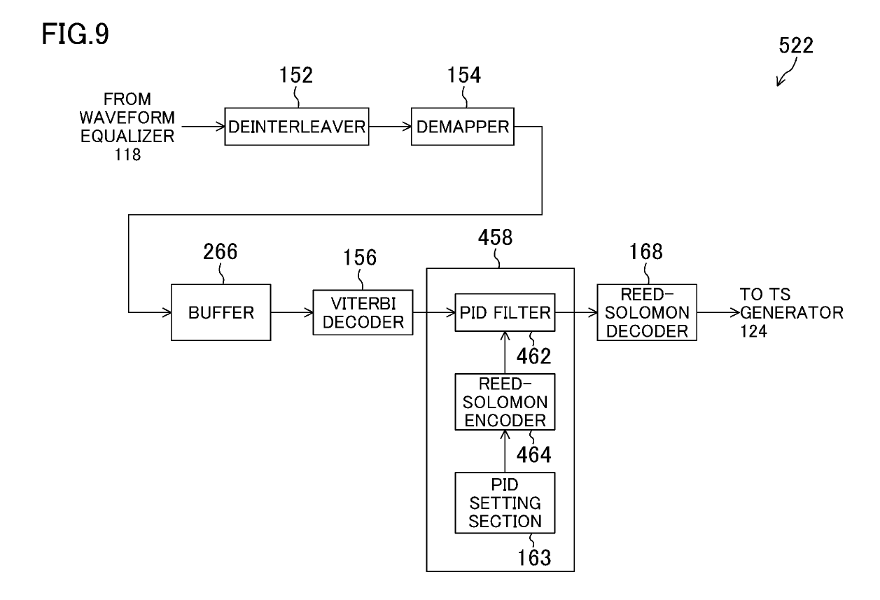

FIG. 9 is a block diagram illustrating a fourth variation of the error corrector of FIG. 5. An error corrector 522 of FIG. 9 is different from the error corrector 422 of FIG. 8 in that a buffer 266 instead of the buffer 166 is provided upstream of the Viterbi decoder 156. The buffer 266 stores a result of the demapping process performed by the demapper 154, and then outputs the stored result to the Viterbi decoder 156. Other configurations are similar to those of the error corrector 422 of FIG. 8.

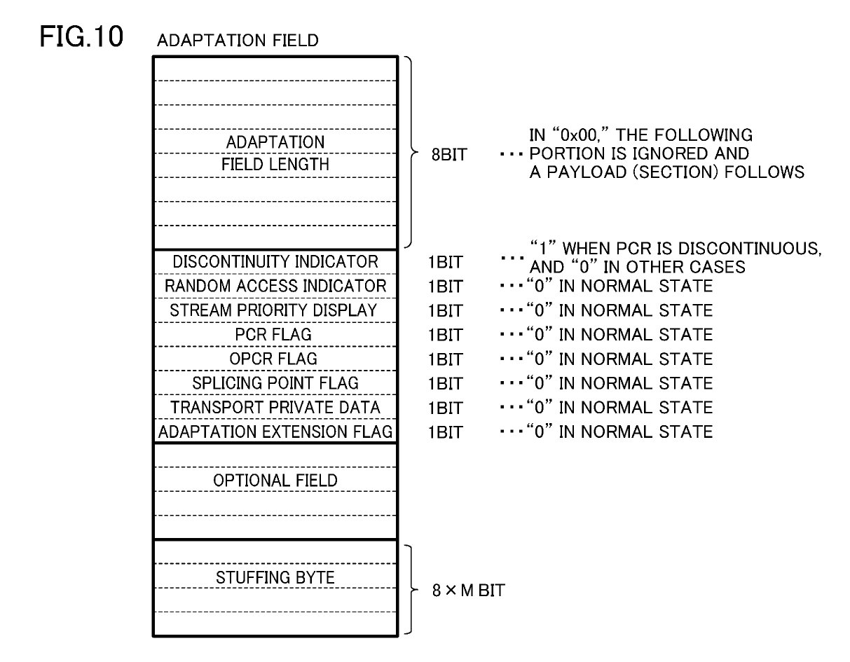

FIG. 10 is a view illustrating an example format of the adaptation field of FIG. 3. As illustrated in FIG. 10, data can be transmitted by using an optional field in the adaptation field. Thus, the broadcast station which performs transmission may transmit data for the section filtering as data of the optional field. The data for the section filtering is, for example, data which allows determination of whether or not the section data transmitted by the packet is necessary.

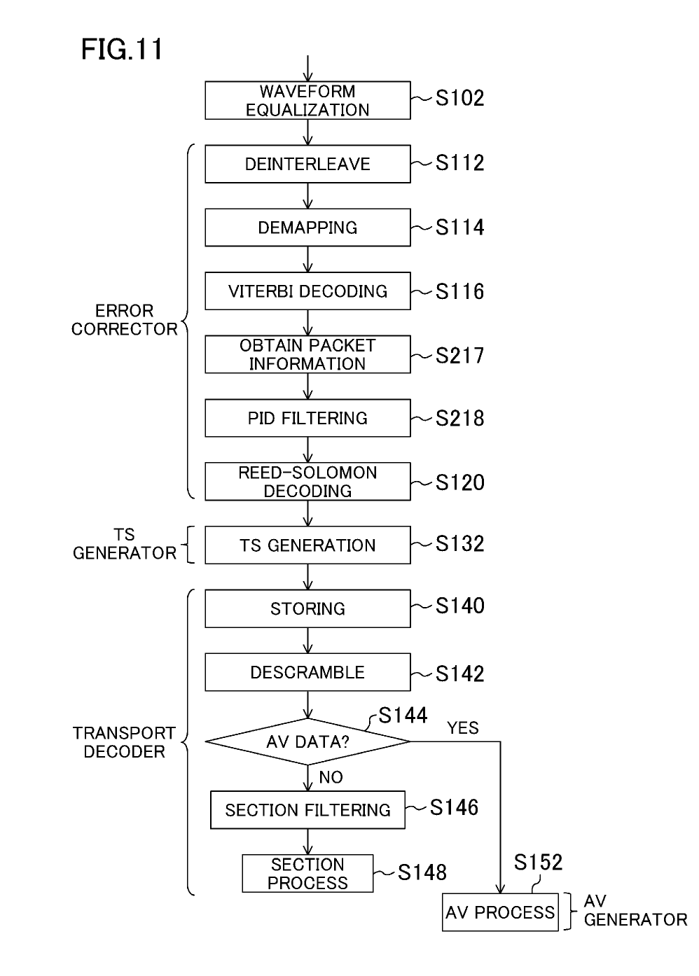

Variations of the data processing device of FIG. 1 will be described below, where the data for the section filtering is thus included in adaptation fields of packets which are transmitted. FIG. 11 is a flow chart illustrating a process flow in a variation of the data processing device of FIG. 1.

In S217 of FIG. 11, the Reed-Solomon decoder 161 of the error corrector 122 of FIG. 5 performs a Reed-Solomon decoding process on part of the result of a Viterbi decoding, the part including TS headers and adaptation fields. The Reed-Solomon decoder 161 outputs the result of the Reed-Solomon decoding process to the PID filter 162. Here, the Reed-Solomon decoder 161 first performs the Reed-Solomon decoding process on the result of the Viterbi decoding to search synchronization bytes, and then performs the Reed-Solomon decoding process also on a series of data from the byte succeeding the synchronization byte through the adaptation fields for one of the packets. The part including the TS headers and the adaptation fields is not encrypted by broadcast encryption. The PID filter 162 obtains the data for the section filtering included in the adaptation fields.

In S218, the filter section 158 performs a PID filtering process on the result of the Viterbi decoding as described below. PIDs of packets which should be passed through the filter section 158 and data for the section filtering to select necessary packets are set in the PID setting section 163. The PID setting section 163 outputs the set PIDs and the set data for the section filtering to the PID filter 162.

Based on the set data for the section filtering and the obtained data for the section filtering, the PID filter 162 determines whether or not the packets are necessary. The PID filter 162 selects packets which are determined to be necessary, and include the packet identifiers set in the PID setting section 163 from the result of the Reed-Solomon decoding process, and outputs the selected packets to the buffer 166. Other processes in FIG. 11 are similar to those of FIG. 4. A similar variation may be valid for the error correctors 222, 322 of FIGS. 6, 7, respectively.

When the data in the adaptation field is thus utilized to select necessary packets before the descrambling process (S142), it is possible to further reduce the number of packets which are subjected to a descrambling process. Thus, power consumption of the data processing device can be reduced. Moreover, when a shared memory is used, it is possible to improve the speed of processes other than those performed by the data processing device.

For the error corrector 422 of FIG. 8, the following variation may be possible. In addition to PIDs, data for section filtering to select necessary packets is set in the PID setting section 163. The PID setting section 163 outputs the set PIDs and the set data for the section filtering to the Reed-Solomon encoder 464.

Based on the data for the section filtering set in the PID setting section 163, the Reed-Solomon encoder 464 generates data of adaptation fields of packets which should be determined to be necessary. The Reed-Solomon encoder 464 performs a Reed-Solomon encoding process on part from the leading portion to the adaptation field of FIG. 3, and outputs the Reed-Solomon encoded PIDs and the Reed-Solomon encoded data of the adaptation fields to the PID filter 462. The encoded PIDs here are the PIDs set in the PID setting section 163, and the contents of the adaptation fields are the data of the adaptation fields of the packets which should be determined to be necessary. Moreover, for each PID, the encoding process is performed on the part from the leading portion to the adaptation field of FIG. 3 in terms of all combinations of values of a transport error indicator and values of a packet unit start indicator.

The PID filter 462 selects packets including the encoded result output from the Reed-Solomon encoder 464 from a result of Viterbi decoding, and outputs the selected packets to the buffer 166. A similar variation is valid for the error corrector 522 of FIG. 9.

Likewise, the transport decoder 132 may perform section filtering by using the data of the adaptation fields prior to a descrambling process. That is, the data for the section filtering to select necessary packets is set in the transport decoder 132. The transport decoder 132 obtains data for the section filtering included in the adaptation fields of the packets, and stores the obtained data.

Based on the set data for the section filtering and the obtained data for the section filtering, the transport decoder 132 determines whether or not the packets are necessary. When the packets are determined to be necessary, the transport decoder 132 selects the packets from TS, and outputs the selected packets to a memory, in which the packets are stored (S140). Then, the transport decoder 132 reads the packets from the memory to perform the descrambling process.

As described above, the transport decoder 132 can also utilize data of the adaptation fields to select necessary packets prior to the descrambling process, and it is possible to further reduce the number of packets which are subjected to the descrambling process.

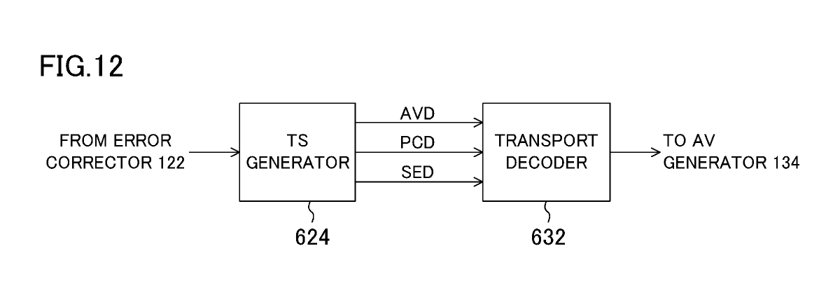

FIG. 12 is a block diagram illustrating a variation of part of the data processing device of FIG. 1. A data processing device of FIG. 12 is different from the data processing device of FIG. 1 in that a TS generator 624 and a transport decoder 632 are provided instead of the TS generator 124 and the transport decoder 132.

The TS generator 624 separates a TS into AV data AVD including data representing video images and data representing audio, section data SED, and particular data PCD such as program clock reference (PCR) which is necessary to generate video images, and outputs the separated data pieces to the transport decoder 632. The transport decoder 632 outputs the AV data AVD without processing to the AV generator 134, and performs necessary processes on the section data SED and the particular data PCD.

With the data processing device of FIG. 12, the amount of data which the transport decoder 632 has to process decreases, so that the load of the transport decoder 632 can be reduced. In particular, when a front end section including the TS generator 624 and a back end section including the transport decoder 632 are integrated into a single LSI, the TS generator 624 is connected to the transport decoder 632 in a chip, so that the configuration as illustrated in FIG. 12 can be easily implemented.

As described above, the present invention is useful to data processing devices, etc.

Many features and advantages of the present invention are obvious from the above description, and hence it is intended to cover all of such features and advantages of the present invention by the appended claims. As many changes and modifications can be easily made by those skilled in the art, the present invention should not be limited to the constructions and operations identical to those illustrated and described herein. Accordingly, it is to be understood that all appropriate modifications and equivalents fall within the scope of the present invention.

What is claimed is:

1. A data processing device comprising:
an error corrector configured to perform demodulation and error correction on a received signal to output error-corrected data, the received signal transmitting packets which include packet identifiers and are encrypted by broadcast encryption; and
a transport stream generator configured to generate a transport stream based on the error-corrected data, wherein
the error corrector selects the packets including a set packet identifier, and outputs the selected packets as the error-corrected data.

2. The data processing device of claim 1, wherein
the error corrector includes
a demapper configured to demodulate the received signal to output demodulated data,
a Viterbi decoder configured to perform Viterbi decoding on the demodulated data to output Viterbi decoded data,
a filter section configured to select the packets including the set packet identifier from the Viterbi decoded data, and
a first Reed-Solomon decoder configured to perform Reed-Solomon decoding on the packets selected by the filter section to output Reed-Solomon decoded packets as the error-corrected data.

3. The data processing device of claim 2, wherein
the filter section includes
a second Reed-Solomon decoder configured to perform Reed-Solomon decoding on part of the Viterbi decoded data, the part including the packet identifiers,
a packet identifier setting section configured to output the set packet identifier, and
a packet identifier filter configured to select packets from data obtained by the Reed-Solomon decoding by the second Reed-Solomon decoder according to the set packet identifier.

4. The data processing device of claim 2, wherein
the filter section includes
a packet identifier setting section configured to output the set packet identifier,
a Reed-Solomon encoder configured to perform Reed-Solomon encoding on the set packet identifier to output Reed-Solomon encoded packet identifier, and
a packet identifier filter configured to select packets from the Viterbi decoded data based on the Reed-Solomon encoded packet identifier.

5. The data processing device of claim 1, wherein
the error corrector includes
a demapper configured to demodulate the received signal to output demodulated data,
a Viterbi decoder configured to perform Viterbi decoding on the demodulated data to output Viterbi decoded data,
a first Reed-Solomon decoder configured to perform Reed-Solomon decoding on the Viterbi decoded data to output Reed-Solomon decoded data, and
a filter section configured to select the packets including the set packet identifier from the Reed-Solomon decoded data, and to output the selected packets as the error-corrected data.

6. The data processing device of claim 1, wherein
the packets transmitted by the received signal include adaptation fields which include data for section filtering, and
the error corrector includes
a demapper configured to demodulate the received signal to output demodulated data,
a Viterbi decoder configured to perform Viterbi decoding on the demodulated data to output Viterbi decoded data,
a filter section configured to determine, based on the data of the adaptation fields of the packets included in the Viterbi decoded data, whether or not the packets are necessary, and to select the packets, each of which is determined to be necessary and includes the set packet identifier, from the Viterbi decoded data, and
a first Reed-Solomon decoder configured to perform Reed-Solomon decoding on the packets selected by the filter section to output Reed-Solomon decoded packets as the error-corrected data.

7. The data processing device of claim 6, wherein
the filter section includes
a second Reed-Solomon decoder configured to perform Reed-Solomon decoding on part of the Viterbi decoded data, the part including the adaptation fields and the packet identifiers of the packets,
a packet identifier setting section configured to output the set packet identifier, and
a packet identifier filter configured to determine, based on the data of the adaptation fields of the packets included in data obtained by the Reed-Solomon decoding by the second Reed-Solomon decoder, whether or not the packets are necessary, and to select the packets, each of which is determined to be necessary and includes the set packet identifier, from the data obtained by the Reed-Solomon decoding by the second Reed-Solomon decoder.

8. The data processing device of claim 6, wherein
the filter section includes
a packet identifier setting section configured to output the set packet identifier,
a Reed-Solomon encoder configured to perform Reed-Solomon encoding on the packet identifier output from the packet identifier setting section and on the data of the adaptation fields of the packets which should be determined to be necessary to output Reed-Solomon encoded packet identifier and Reed-Solomon encoded data of the adaptation fields, and
a packet identifier filter configured to select packets from the Viterbi decoded data based on the Reed-Solomon encoded packet identifier and the Reed-Solomon encoded data of the adaptation fields.

9. The data processing device of claim 1, further comprising:
a transport decoder configured to decrypt, with respect to the broadcast encryption, the transport stream generated by the transport stream generator, and to perform section filtering on the transport stream; and
a video generator configured to generate a video signal from a decrypted transport stream obtained by the transport decoder.

10. The data processing device of claim 9, wherein
the packets transmitted by the received signal include adaptation fields which include data for the section filtering, and
the transport decoder refers to the adaptation fields of the packets to determine whether or not the packets are necessary, and when the packets are determined to be necessary, the transport decoder decrypts the packets with respect to the broadcast encryption.

11. The data processing device of claim 1, wherein
the transport stream generator is configured to separate the transport stream into data representing a video image, section data, and program clock reference (PCR) data, and to output the separated data pieces.

12. A data processing method comprising:
performing demodulation and error correction on a received signal to output error-corrected data, the received signal transmitting packets which include packet identifiers and are encrypted by broadcast encryption; and
generating a transport stream based on the error-corrected data, wherein
in the performing, the packets including a set packet identifier are selected, and the selected packets are output as the error-corrected data.

13. The method of claim 12, wherein
the packets transmitted by the received signal include adaptation fields which include data for section filtering, and
the method further includes
determining whether or not the packets are necessary based on the data of the adaptation fields of the packets, and
decrypting the packets with respect to the broadcast encryption when the packets are determined to be necessary in the determining.
